(19) United States
(12) Patent Application Publication
(10) Pub. No.: US 2019/0267346 A1
(43) Pub. Date: Aug. 29, 2019

(54) FLUX TRANSFER TOOL AND FLUX TRANSFER METHOD

(71) Applicant: POWERTECH TECHNOLOGY INC., HSINCHU COUNTY (TW)

(72) Inventors: Kun-Chi Hsu, HSINCHU COUNTY (TW); Sheng-Tou Tseng, HSINCHU COUNTY (TW); Hung-Chieh Huang, HSINCHU COUNTY (TW)

(21) Appl. No.: 15/908,759

(22) Filed: Feb. 28, 2018

(51) Int. Cl. H01L 23/00

(52) U.S. Cl. CPC H01L 24/75; H01L 24/81; H01L 2224/7501; H01L 2224/75501; H01L 2224/81024; H01L 2224/81815; H01L 2224/75252

(57) ABSTRACT

A flux transfer tool includes a heater, a flux supplier, an ejector and a baseplate. The heater has a nozzle. The flux supplier is connected to the heater and contains a flux. The ejector is connected to the heater. The baseplate has a plurality of first holes formed thereon. The flux supplier supplies the flux to the heater, the heater heats the flux, and the ejector ejects the flux from the nozzle to spray the flux on the baseplate.

### BACKGROUND OF THE INVENTION

### 1. Field of the Invention

The invention relates to a flux transfer tool and a flux transfer method and, more particularly, to a flux transfer tool and a flux transfer method for improving a flux transfer process of a ball grid array (BGA) package and Chip Scale Package (CSP).

### 2. Description of the Prior Art

BGA and CSP techniques have become more common in recent years for connecting high-density IC components onto circuit boards. In BGA and CSP techniques, a flux transfer tool is used to transfer flux to a plurality of bond pads of a substrate to remove oxidized film and to provisionally fix solder balls before the solder balls are mounted on the bond pads by a reflow process.

Referring to FIGS. 1 to 3, FIG. 1 is a side view illustrating a flux transfer tool 1 of the prior art, FIG. 2 is a side view illustrating the flux transfer pins 10 adhered with the flux 12, and FIG. 3 is a side view illustrating the flux 12 transferred from the flux transfer pins 10 to the bond pads 20 of the substrate 2. As shown in FIG. 1, the flux transfer tool 1 comprises a plurality of flux transfer pins 10. A flux 12 in a flux tray 14 is extended to a uniform thickness by means of a scraper 16. Then, the flux transfer tool 1 is driven to move towards the flux tray 14, such that the flux 12 adheres to each of the flux transfer pins 10 uniformly, as shown in FIG. 2. Then, the flux transfer tool 1 is driven to move to a position above a substrate 2 and move towards the substrate 2, such that the flux 12 is transferred from the flux transfer pins 10 to a plurality of bond pads 20 of the substrate 2, as shown in FIG. 3.

As demand for electronic devices that are smaller and more powerful continues to increase, the size of the solder ball and the pitch between two adjacent solder balls in a BGA and CSP package become smaller and smaller accordingly. However, due to the limitation of the spacing S between two adjacent flux transfer pins 10, the size of the solder ball cannot be smaller than about 0.15 mm and the pitch between two adjacent solder balls cannot be smaller than about 0.3 mm, such that the development of the electronic devices is limited.

### SUMMARY OF THE INVENTION

The invention provides a flux transfer tool and a flux transfer method for improving a flux transfer process of a BGA and CSP package, so as to solve the aforesaid problems.

According to an embodiment of the invention, a flux transfer tool comprises a heater, a flux supplier, an ejector and a baseplate. The heater has a nozzle. The flux supplier is connected to the heater and contains a flux. The ejector is connected to the heater. The baseplate has a plurality of first holes formed thereon. The flux supplier supplies the flux to the heater, the heater heats the flux, and the ejector ejects the flux from the nozzle to spray the flux on the baseplate.

According to another embodiment of the invention, a flux transfer method is performed by a flux transfer tool. The flux transfer tool comprises a heater, a flux supplier, an ejector and a baseplate. The heater has a nozzle. The flux supplier is connected to the heater and contains a flux. The ejector is connected to the heater. The baseplate has a plurality of first holes formed thereon. The flux transfer method comprises steps of placing the baseplate on a substrate, wherein the substrate has a plurality of bond pads and the first holes are aligned with the bond pads; supplying the flux to the heater by the flux supplier; heating the flux by the heater; and ejecting the flux from the nozzle by the ejector to spray the flux on the baseplate, such that the flux is formed on the bond pads through the first holes.

As mentioned in the above, the invention utilizes the heater to heat the flux to reduce the viscosity of the flux, such that the flux can be ejected from the nozzle of the heater and sprayed on the baseplate. Then, the flux can be formed on the bond pads of the substrate through the first holes of the baseplate. Since the first holes on the baseplate can be adjusted in accordance with the size of the solder ball and the pitch between two adjacent solder balls, the BGA and CSP package can be miniaturized according to practical demand. Accordingly, the invention can improve the flux transfer process of the BGA and CSP package and save the cost of manufacturing the flux transfer pin of the prior art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a side view illustrating a flux transfer tool of the prior art.

FIG. 2 is a side view illustrating the flux transfer pins adhered with the flux.

FIG. 3 is a side view illustrating the flux transferred from the flux transfer pins to the bond pads of the substrate.

FIG. 4 is a perspective view illustrating a flux transfer tool according to an embodiment of the invention.

FIG. 5 is a perspective view illustrating the baseplate and the substrate.

FIG. 6 is a perspective view illustrating the baseplate placed on the substrate.

FIG. 7 is a perspective view illustrating the flux ejected from the nozzle of the heater and sprayed on the baseplate.

FIG. 8 is a perspective view illustrating the baseplate removed from the substrate.

FIG. 9 is a flowchart illustrating a flux transfer method according to an embodiment of the invention.

FIG. 10 is a perspective view illustrating a flux transfer tool according to another embodiment of the invention.

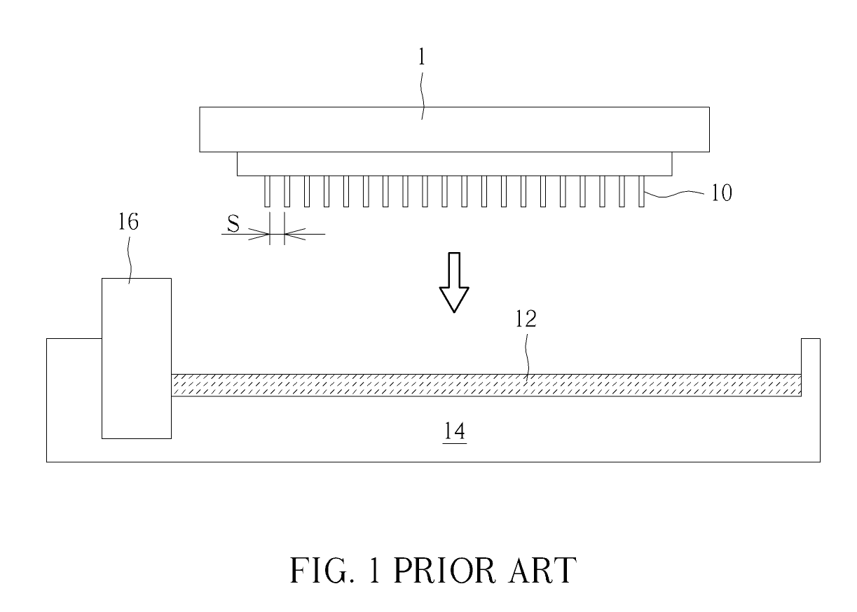

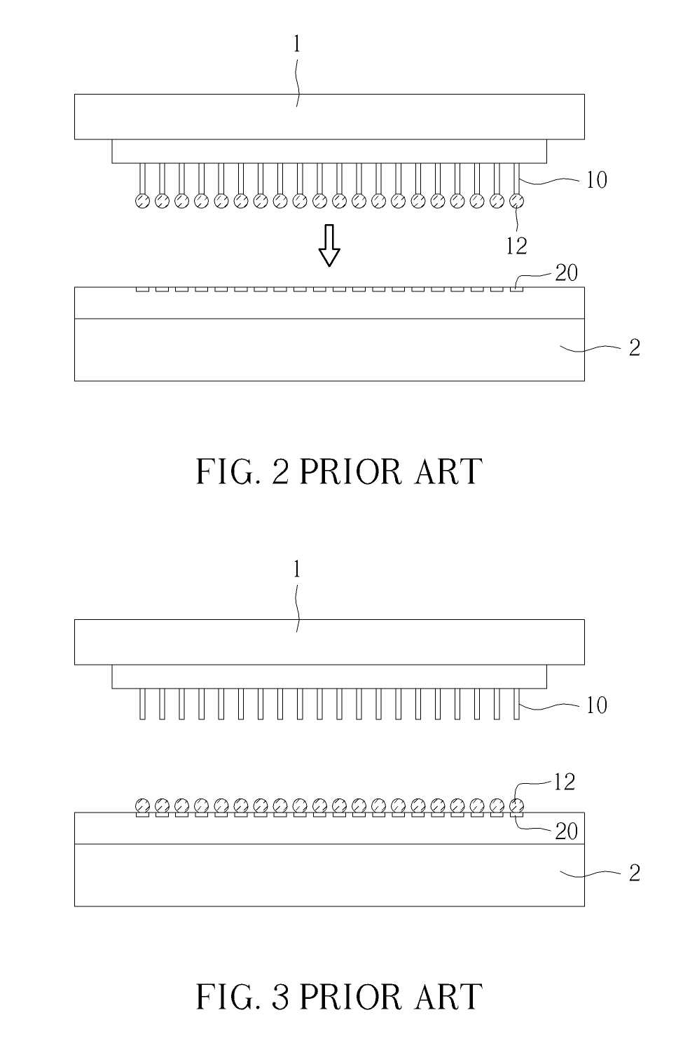

### DETAILED DESCRIPTION

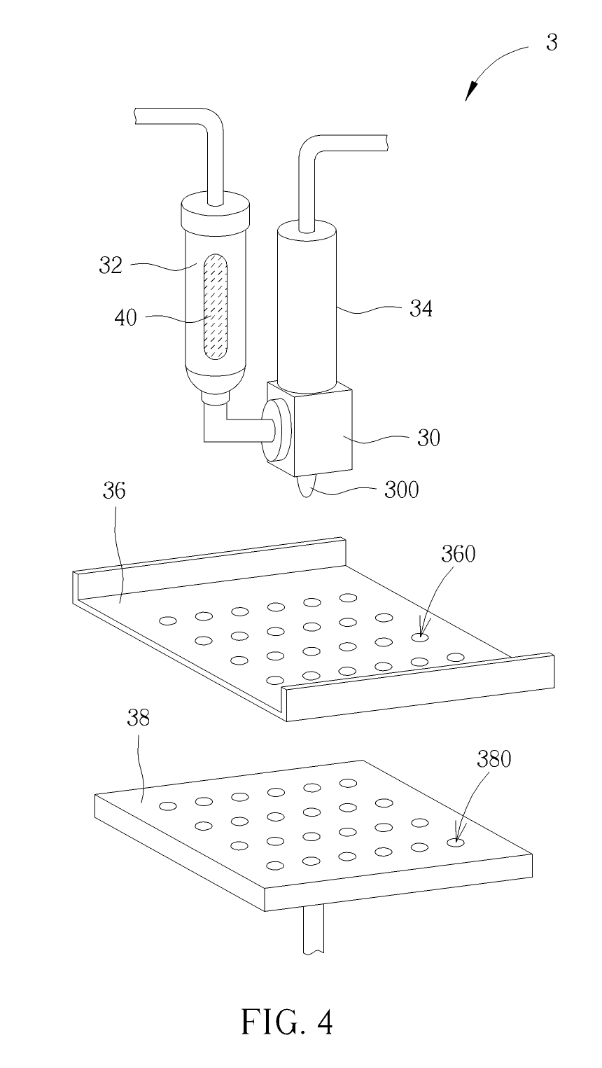

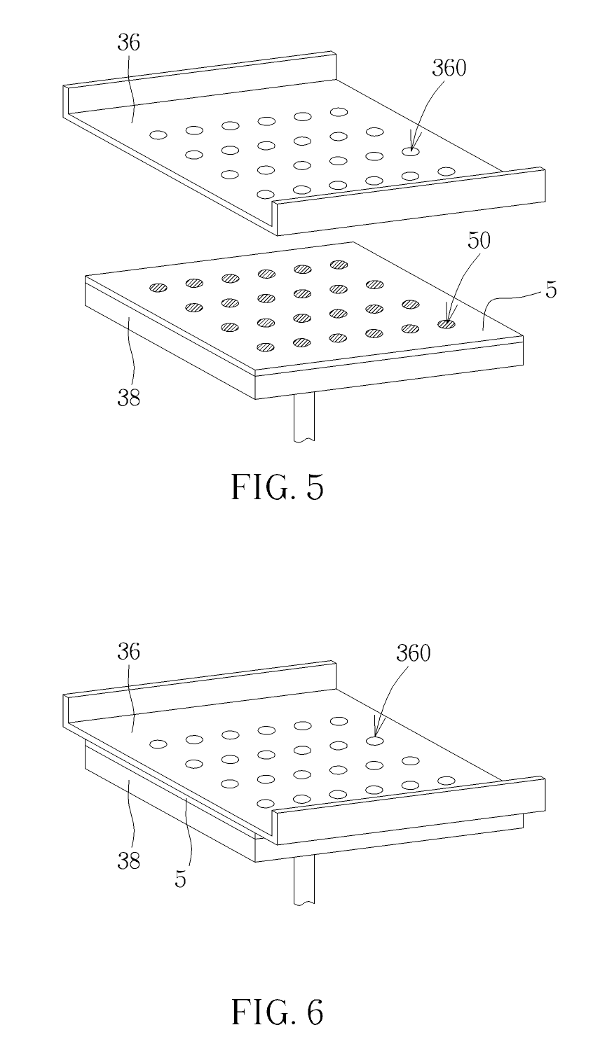

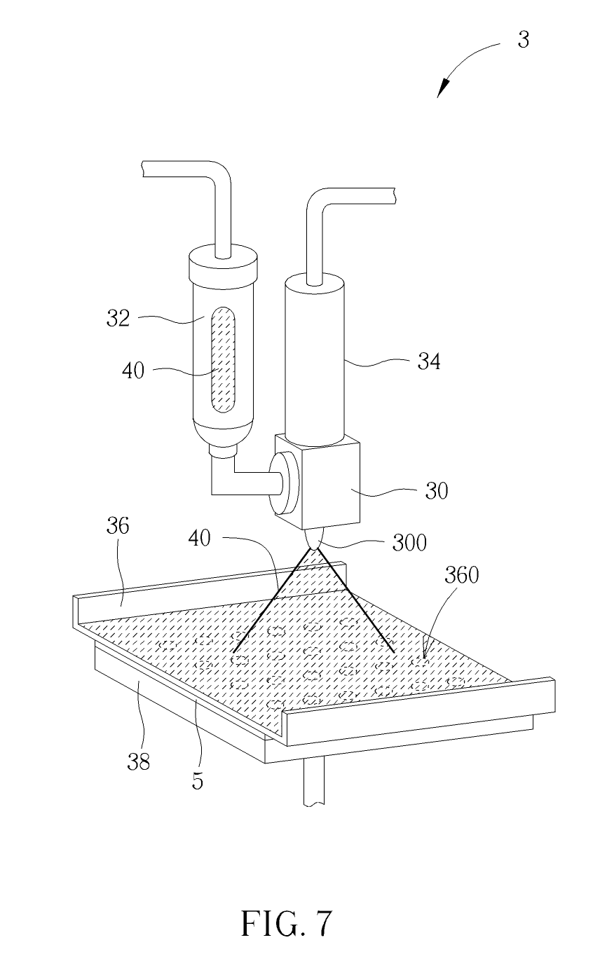

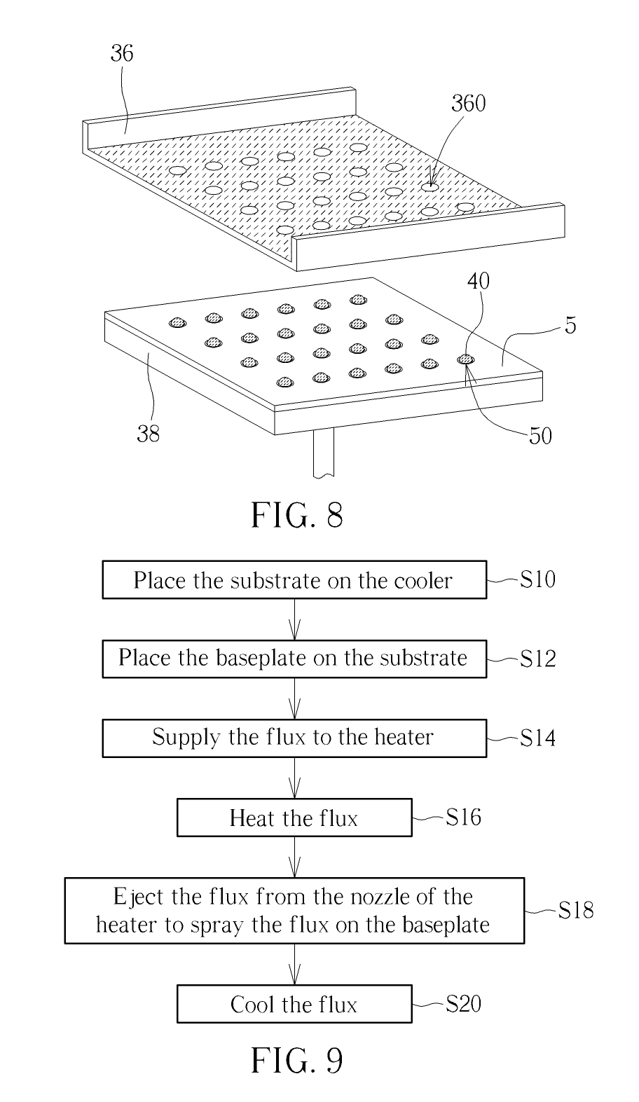

Referring to FIGS. 4 to 9, FIG. 4 is a perspective view illustrating a flux transfer tool 3 according to an embodiment of the invention, FIG. 5 is a perspective view illustrating the baseplate 36 and the substrate 5, FIG. 6 is a perspective view illustrating the baseplate 36 placed on the substrate 5, FIG. 7 is a perspective view illustrating the flux 40 ejected from the nozzle 300 of the heater 30 and sprayed on the baseplate 36, FIG. 8 is a perspective view illustrating the baseplate 36 removed from the substrate 5, and FIG. 9 is a flowchart illustrating a flux transfer method according to an embodiment of the invention.

As shown in FIG. 4, the flux transfer tool 3 comprises a heater 30, a flux supplier 32, an ejector 34, a baseplate 36 and a cooler 38. The heater 30 has a nozzle 300. The flux supplier 32 is connected to the heater 30 and contains a flux 40. The ejector 34 is connected to the heater 30. The baseplate 36 has a plurality of first holes 360 formed thereon. In this embodiment, the baseplate 36 may be, but not limited to, a stencil. The cooler 38 has a plurality of second holes 380 formed thereon. In this embodiment, the second holes 380 of cooler 38 may be arranged corresponding to the first holes 360 of the baseplate 36, but is not so limited.

As shown in FIGS. 5 to 8, the flux transfer tool 3 is used to transfer the flux 40 to a substrate 5 through the baseplate 36. The substrate 5 may be an IC package or the like. The substrate 5 has a plurality of bond pads 50, wherein the first holes 360 of the baseplate 36 and the second holes 380 of the cooler 38 are arranged corresponding to the bond pads 50 of the substrate 5.

The flux transfer method of the invention shown in FIG. 9 is performed by the flux transfer tool 3. To transfer the flux 40 to the substrate 5 through the baseplate 36, first, the substrate 5 is placed on the cooler 38, as shown in FIG. 5 and step S10 in FIG. 9. Then, the baseplate 36 is placed on the substrate 5 and the first holes 360 are aligned with the bond pads 50, as shown in FIG. 6 and step S12 in FIG. 9.

Then, the flux supplier 32 supplies the flux 40 to the heater 30, as shown in step S14 in FIG. 9. Then, the heater 30 heats the flux 40 to reduce the viscosity of the flux 40, as shown in step S16 in FIG. 9. Then, the ejector 34 ejects the flux 40 from the nozzle 300 of the heater 30 to spray the flux 40 on the baseplate 36, such that the flux 40 is formed on the bond pads 50 of the substrate 5 through the first holes 360 of the baseplate 36, as shown in FIG. 7 and step S18 in FIG. 9. In this embodiment, the ejector 34 may eject the flux 40 from the nozzle 300 of the heater 30 by pressure.

In this embodiment, the cooler 38 is configured to cool the flux 40 formed on the bond pads 50 of the substrate 5. When the flux 40 is sprayed on the baseplate 36 and formed on the bond pads 50 of the substrate 5, the flux 40 is cooled by the cooler 38, such that the viscosity of the flux 40 increases, as shown in step S20 in FIG. 9. Accordingly, the flux 40 can be positioned on the bond pads 50 stably. In this embodiment, the cooler 38 may blow air out of the second holes 380 to cool the flux 40 on the bond pads 50 of the substrate 5. Furthermore, the flux 40 may be cooled by the cooler 38 to be lower than room temperature.

Then, the baseplate 36 can be removed from the substrate 5 to complete the flux transfer process, as shown in FIG. 8. In this embodiment, the first holes 360 on the baseplate 36 can be adjusted in accordance with the size of the solder ball and the pitch between two adjacent solder balls, so the BGA and CSP package can be miniaturized according to practical demand. Accordingly, the invention can improve the flux transfer process of the BGA and CSP package and save the cost of manufacturing the flux transfer pin of the prior art.

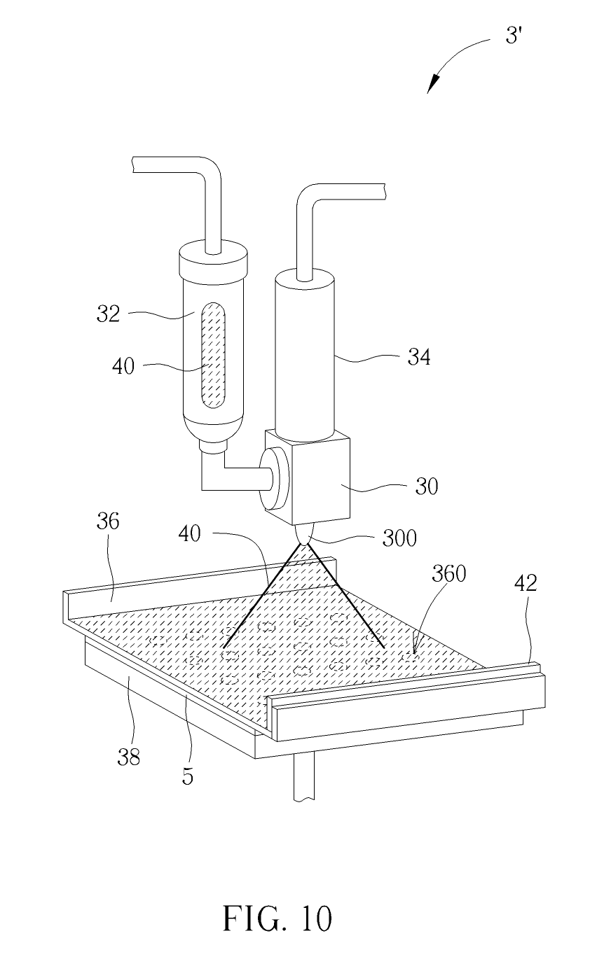

Referring to FIG. 10, FIG. 10 is a perspective view illustrating a flux transfer tool 3′ according to another embodiment of the invention. The main difference between the flux transfer tool 3′ and the aforesaid flux transfer tool 3 is that the flux transfer tool 3′ further comprises a scraper 42 movably disposed on the baseplate 36, as shown in FIG. 10. Accordingly, in this embodiment, when the flux 40 is sprayed on the baseplate 36, the scraper 42 can be moved to scrape the baseplate 36 to fill the first holes 360 with the flux 40 uniformly.

As mentioned in the above, the invention utilizes the heater to heat the flux to reduce the viscosity of the flux, such that the flux can be ejected from the nozzle of the heater and sprayed on the baseplate. Then, the flux can be formed on the bond pads of the substrate through the first holes of the baseplate. Since the first holes on the baseplate can be adjusted in accordance with the size of the solder ball and the pitch between two adjacent solder balls, the BGA and CSP package can be miniaturized according to practical demand. Accordingly, the invention can improve the flux transfer process of the BGA and CSP package and save the cost of manufacturing the flux transfer pin of the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flux transfer tool comprising:
a heater having a nozzle;
a flux supplier connected to the heater and containing a flux;
an ejector connected to the heater; and
a baseplate having a plurality of first holes formed thereon;
wherein the flux supplier supplies the flux to the heater, the heater heats the flux, and the ejector ejects the flux from the nozzle to spray the flux on the baseplate.

2. The flux transfer tool of claim 1, further comprising a cooler configured to cool the flux.

3. The flux transfer tool of claim 2, wherein the cooler has a plurality of second holes formed thereon, the second holes are arranged corresponding to the first holes, and the cooler blows air out of the second holes to cool the flux.

4. The flux transfer tool of claim 1, further comprising a scraper movably disposed on the baseplate, wherein when the flux is sprayed on the baseplate, the scraper scrapes the baseplate to fill the first holes with the flux.

5. The flux transfer tool of claim 1, wherein the first holes of the baseplate are arranged corresponding to a plurality of bond pads of a substrate.

6. A flux transfer method performed by a flux transfer tool, the flux transfer tool comprising a heater, a flux supplier, an ejector and a baseplate, the heater having a nozzle, the flux supplier being connected to the heater and containing a flux, the ejector being connected to the heater, the baseplate having a plurality of first holes formed thereon, the flux transfer method comprising steps of:
placing the baseplate on a substrate, wherein the substrate has a plurality of bond pads and the first holes are aligned with the bond pads;
supplying the flux to the heater by the flux supplier;
heating the flux by the heater; and
ejecting the flux from the nozzle by the ejector to spray the flux on the baseplate, such that the flux is formed on the bond pads through the first holes.

7. The flux transfer method of claim 6, wherein the flux transfer tool further comprises a cooler, the flux transfer method further comprises steps of:
placing the substrate on the cooler; and
cooling the flux on the bond pads by the cooler.

8. The flux transfer method of claim 7, wherein the cooler has a plurality of second holes formed thereon, the second holes are arranged corresponding to the bond pads, the flux transfer method further comprises steps of:
blowing air out of the second holes to cool the flux on the bond pads by the cooler.

9. The flux transfer method of claim 1, wherein the flux transfer tool further comprises a scraper movably disposed on the baseplate, the flux transfer method further comprises steps of:
moving the scraper to scrape the baseplate to fill the first holes with the flux when the flux is sprayed on the baseplate.
